(19) United States
(12) Patent Application Publication
(10) Pub. No.: US 2025/0087452 A1
(43) Pub. Date: Mar. 13, 2025

(54) MULTIPLE CHARGED PARTICLE BEAM WRITING APPARATUS AND MULTIPLE CHARGED PARTICLE BEAM WRITING METHOD

(71) Applicant: NuFlare Technology, Inc., Yokohama-shi (JP)

(72) Inventors: Yasuo KATO, Yokohama-shi (JP); Ryoh KAWANA, Yokohama-shi (JP)

(73) Assignee: NuFlare Technology, Inc., Yokohama-shi (JP)

(21) Appl. No.: 18/959,954

(22) Filed: Nov. 26, 2024

Related U.S. Application Data
(63) Continuation of application No. PCT/JP2023/019566, filed on May 25, 2023.

(30) Foreign Application Priority Data
Jun. 3, 2022 (JP) 2022-090905

(51) Int. Cl. H01J 37/304; H01J 37/317

(52) U.S. Cl. CPC H01J 37/304; H01J 37/3177

(57) ABSTRACT

A multiple-beam-writing-apparatus includes a defect-correction-data-generation-circuit to generate defect correction data defining a dose modulation rate for correction by distributing a dose at a position of a defective beam, being always-OFF, in the multiple beams to at least one of other pixels, using a dose distribution where each position in a unit region on a target object is defined by a uniform dose, regardless of writing pattern, a dose-correction-circuit to read, for each writing pattern, the defect correction data from the storage-device, to correct the individual dose at each position according to the writing pattern concerned by a dose distribution using a value obtained by multiplying the individual dose at each position by the dose modulation rate defined in the read defect correction data, and to obtain a corrected dose, and a writing-mechanism to write the writing pattern with the multiple beams of the corrected dose.

### CROSS-REFERENCE TO RELATED APPLICATION

This application is a continuation application based upon and claims the benefit of priority from prior Japanese Patent Application No. 2022-090905 (application number) filed on Jun. 3, 2022 in Japan, and International Application PCT/JP2023/019566, the International Filing Date of which is May 25, 2023. The contents described in JP2022-090905 and PCT/JP2023/019566 are incorporated herein by reference.

### BACKGROUND OF THE INVENTION

### Field of the Invention

An aspect of an embodiment of the present invention relate to a multiple charged particle beam writing apparatus and a multiple charged particle beam writing method. For example, they relate to a method for reducing a dimensional deviation of a pattern written using multiple beams.

### Description of Related Art

The lithography technique which advances miniaturization of semiconductor devices is extremely important as a unique process whereby patterns are formed in semiconductor manufacturing. In recent years, with high integration of LSI, the line width (critical dimension) necessary for semiconductor device circuits is becoming increasingly narrower year by year. The electron beam writing technique, which intrinsically has excellent resolution, is used for writing or “drawing” a mask pattern on a mask blank with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

In multiple beam writing, the dose of each beam is controlled based on an irradiation time. However, it may happen that to control the irradiation time becomes difficult because of failures of a blanking control mechanism, etc., and therefore, a defective beam being an “always-OFF beam” applying no beam may be generated. If a target object is not irradiated with a necessary dose, a problem occurs in that a shape error of a pattern formed on the target object is generated. To solve this problem, there is proposed a method for performing a correction by calculating the dose of each pixel in accordance with a pattern to be written, and by sharing (distributing) the insufficient dose amount at a pixel associated with (irradiated with) an “always-OFF” defective beam among peripheral beams of the defective beam (e.g., refer to Japanese Patent Application Laid-open (JP-A) No. 2019-033117). However, data processing for correcting a defective beam takes time. Therefore, a problem may occur in that data generation cannot keep up with the speed of writing processing.

### BRIEF SUMMARY OF THE INVENTION

According to one aspect of the present invention, a multiple charged particle beam writing apparatus includes
a beam forming mechanism configured to form multiple charged particle beams;
a defect correction data generation circuit configured to generate defect correction data which defines a dose modulation rate for performing correction by distributing a dose at a position associated with a defective beam, being always-OFF, in the multiple charged particle beams to at least one of other pixels, using a dose distribution in which each position in a unit region on a target object, corresponding to an irradiation region of a whole of the multiple charged particle beams, is defined by a uniform dose, regardless of writing pattern to be written;
a storage device configured to store the defect correction data;
a dose calculation circuit configured to calculate, for each writing pattern, an individual dose at each position on the target object, in accordance with a writing pattern concerned;
a dose correction circuit configured to read, for the each writing pattern, the defect correction data from the storage device, to correct the individual dose at the each position on the target object in accordance with the writing pattern concerned by performing a dose distribution using a value obtained by multiplying the individual dose at the each position on the target object by the dose modulation rate defined in the defect correction data having been read, and to obtain a corrected dose; and
a writing mechanism configured to write the writing pattern on the target object by using the multiple charged particle beams with the corrected dose.

According to another aspect of the present invention, a multiple charged particle beam writing method includes
forming multiple charged particle beams;
generating defect correction data which defines a dose modulation rate for performing correction by distributing a dose at a position associated with a defective beam, being always-OFF, in the multiple charged particle beams to at least one of other pixels, using a dose distribution in which each position in a unit region on a target object, corresponding to an irradiation region of a whole of the multiple charged particle beams, is defined by a uniform dose, regardless of writing pattern to be written;
storing the defect correction data in a storage device;
calculating, for each writing pattern, an individual dose at each position on the target object, in accordance with a writing pattern concerned;
reading, for the each writing pattern, the defect correction data from the storage device, correcting the individual dose at the each position on the target object in accordance with the writing pattern concerned by performing a dose distribution using a value obtained by multiplying the individual dose at the each position on the target object by the dose modulation rate defined in the defect correction data having been read, and obtaining a corrected dose; and
writing the writing pattern on the target object by using the multiple charged particle beams with the corrected dose.

### BRIEF DESCRIPTION OF THE DRAWINGS

FIG. 1 is a schematic diagram showing a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram illustrating an example of a writing operation according to the first embodiment;

FIG. 5 is an illustration showing an example of an irradiation region of multiple beams and a writing target pixel according to the first embodiment;

FIG. 6 is an illustration showing an example of a writing method of multiple beams according to the first embodiment;

FIG. 7 is a flowchart showing an example of main steps of a writing method according to the first embodiment;

FIG. 8A is an illustration showing a beam position deviation and a position deviation periodicity according to the first embodiment;

FIG. 8B is an illustration showing a beam position deviation and a position deviation periodicity according to the first embodiment;

FIG. 9A is an illustration showing an example of a method for correcting a position deviation according to the first embodiment;

FIG. 9B is an illustration showing an example of a method for correcting a position deviation according to the first embodiment;

FIG. 10 is an illustration showing an example of a dose map for a rectangular unit region for defect correction according to the first embodiment;

FIG. 11A is an illustration showing an example of a method for correcting a defect by multiple writing according to the first embodiment;

FIG. 11B is an illustration showing an example of a method for correcting a defect by multiple writing according to the first embodiment;

FIG. 12 is an illustration showing an example of a method for correcting a defect by using peripheral pixels according to the first embodiment; and

FIG. 13 is an illustration showing another example of the method for correcting a defect by using peripheral pixels according to the first embodiment.

### DETAILED DESCRIPTION OF THE INVENTION

Embodiments below provide an apparatus and method which can avoid that data processing for correcting a defective beam cannot keep up with the speed of writing processing in multiple beam writing.

Embodiments below describe a configuration in which an electron beam is used as an example of a charged particle beam. The charged particle beam is not limited to the electron beam, and other charged particle beams such as an ion beam may also be used.

### First Embodiment

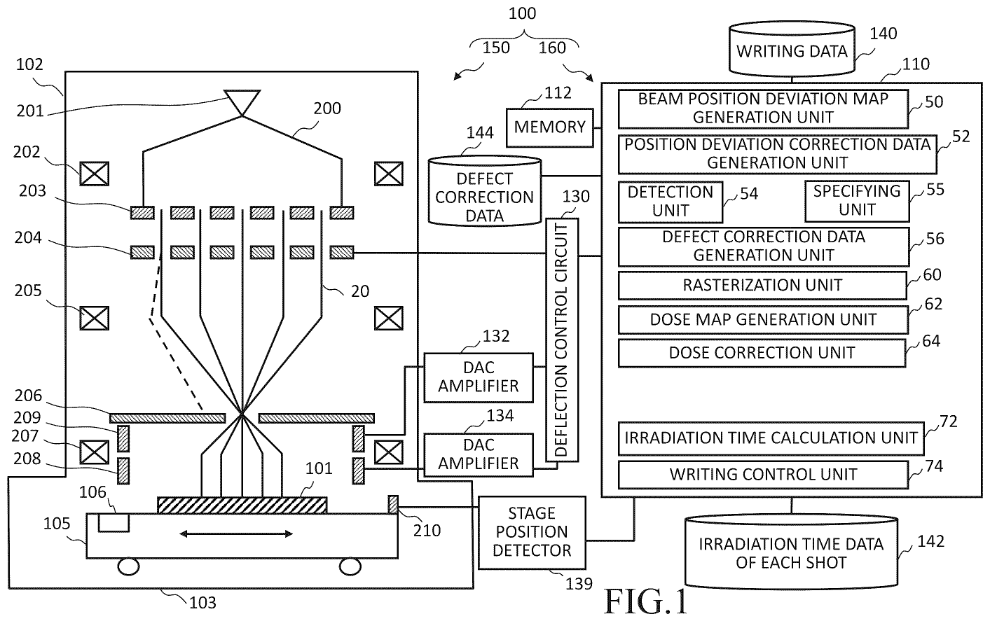

FIG. 1 is a schematic diagram showing a configuration of a writing or “drawing” apparatus according to a first embodiment. As shown in FIG. 1, a writing apparatus 100 includes a writing mechanism 150 and a control system circuit 160. The writing apparatus 100 is an example of a multiple charged particle beam writing apparatus. The writing mechanism 150 includes an electron beam column 102 (multiple electron beam column) and a writing chamber 103. In the electron beam column 102, there are disposed an electron gun 201, an illumination lens 202, a shaping aperture array substrate 203, a blanking aperture array mechanism 204, a reducing lens 205, a limiting aperture substrate 206, an objective lens 207, a deflector 208, and a deflector 209. In the writing chamber 103, an XY stage 105 is disposed. On the XY stage 105, there is placed a target object or “sample” 101 such as a mask blank, on which resist has been applied, serving as a writing target substrate when writing is performed. The target object 101 is, for example, an exposure mask used in fabricating semiconductor devices, or a semiconductor substrate (silicon wafer) for fabricating semiconductor devices. Furthermore, on the XY stage 105, a mirror 210 for measuring the position of the XY stage 105 is placed. Moreover, a Faraday cup 106 is placed on the XY stage 105.

The control system circuit 160 includes a control computer 110, a memory 112, a deflection control circuit 130, DAC (digital-analog converter) amplifier units 132 and 134, a stage position detector 139, and storage devices 140, 142, and 144 such as magnetic disk drives. The control computer 110, the memory 112, the deflection control circuit 130, the DAC amplifier units 132 and 134, the stage position detector 139, and the storage devices 140, 142, and 144 are connected to each other through a bus (not shown). The DAC amplifier units 132 and 134, and the blanking aperture array mechanism 204 are connected to the deflection control circuit 130. Outputs of the DAC amplifier unit 132 are connected to the deflector 209. Outputs of the DAC amplifier unit 134 are connected to the deflector 208. The deflector 208 is composed of at least four electrodes (or “poles”), and controlled by the deflection control circuit 130 through a corresponding amplifier, disposed for each electrode, of the DAC amplifier unit 134. The deflector 209 is composed of at least four electrodes (or “poles”), and controlled by the deflection control circuit 130 through a corresponding amplifier, disposed for each electrode, of the DAC amplifier unit 132. The stage position detector 139 emits a laser light to the mirror 210 on the XY stage 105, and receives a reflected light from the mirror 210. The stage position detector 139 measures the position of the XY stage 105, based on the principle of laser interferometry which uses information of the reflected light.

In the control computer 110, there are arranged a beam position deviation map generation unit 50, a position deviation correction data generation unit 52, a detection unit 54, a specifying unit 55, a defect correction data generation unit 56, a rasterization unit 60, a dose map generation unit 62, a dose correction unit 64, an irradiation time calculation unit 72, and a writing control unit 74. Each of the “ . . . units” such as the beam position deviation map generation unit 50, the position deviation correction data generation unit 52, the detection unit 54, the specifying unit 55, the defect correction data generation unit 56, the rasterization unit 60, the dose map generation unit 62, the dose correction unit 64, the irradiation time calculation unit 72, and the writing control unit 74 includes processing circuitry. The processing circuitry includes, for example, an electric circuit, computer, processor, circuit board, quantum circuit, or semiconductor device. Each “ . . . unit” may use common processing circuitry (the same processing circuitry), or different processing circuitry (separate processing circuitry). Information input/output to/from the beam position deviation map generation unit 50, the position deviation correction data generation unit 52, the detection unit 54, the specifying unit 55, the defect correction data generation unit 56, the rasterization unit 60, the dose map generation unit 62, the dose correction unit 64, the irradiation time calculation unit 72, and the writing control unit 74, and information being operated are stored in the memory 112 each time.

Writing data is input from the outside of the writing apparatus 100, and stored in the storage device 140. The writing data generally defines information on a plurality of figure patterns to be written. Specifically, it defines a figure code, coordinates, size, etc. of each figure pattern.

FIG. 1 shows a configuration necessary for describing the first embodiment. Other configuration elements generally necessary for the writing apparatus 100 may also be included therein.

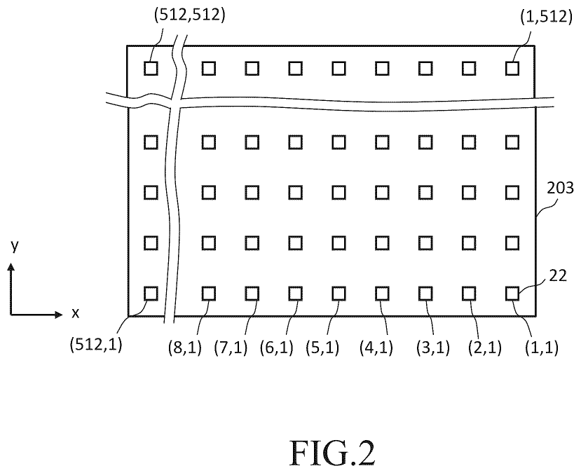

FIG. 2 is a conceptual diagram showing a configuration of a shaping aperture array substrate according to the first embodiment. As shown in FIG. 2, holes (openings) 22 of p rows long (length in the y direction) and q columns wide (width in the x direction) (p≥2, q≥2) are formed, like a matrix, at a predetermined arrangement pitch in the shaping aperture array substrate 203. In the case of FIG. 2, for example, holes 22 of 512×512, that is 512 (rows of holes arrayed in the y direction)×512 (columns of holes arrayed in the x direction), are formed. Each of the holes 22 is rectangular, including square, having the same dimension and shape as each other. Alternatively, each of the holes 22 may be a circle with the same diameter as each other. The shaping aperture array substrate 203 (beam forming mechanism) forms multiple beams 20. Specifically, the multiple beams 20 are formed by letting portions of an electron beam 200 individually pass through a corresponding one of a plurality of holes 22. The method of arranging the holes 22 is not limited to the case of FIG. 2 where the holes are arranged like a grid in the width and length directions. For example, with respect to the x-direction kth and (k+1)th rows which are arrayed in the length direction (in the y direction), each hole in the kth row and each hole in the (k+1)th row may be arranged mutually displaced in the width direction (in the x direction) by a dimension “a”. Similarly, with respect to the x-direction (k+1)th and (k+2)th rows which are arrayed in the length direction (in the y direction), each hole in the (k+1)th row and each hole in the (k+2)th row may be arranged mutually displaced in the width direction (in the x direction) by a dimension “b”.

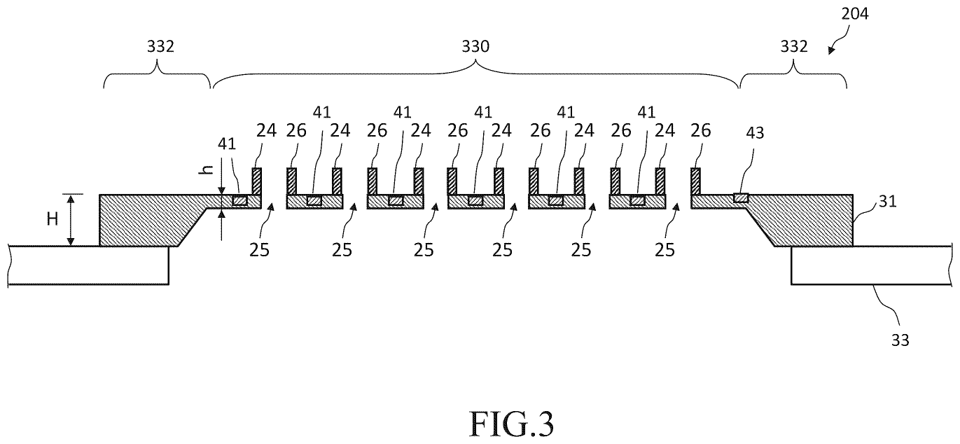

FIG. 3 is a sectional view showing a configuration of a blanking aperture array mechanism according to the first embodiment. With regard to the structure of the blanking aperture array mechanism 204, as shown in FIG. 3, a semiconductor substrate 31 made of silicon, etc. is placed on a support table 33. The central part of the substrate 31 is shaved, for example, from the back side and processed into a membrane region 330 (the first region) having a thin film thickness h. The periphery surrounding the membrane region 330 is an outer peripheral region 332 (the second region) having a thick film thickness H. The upper surface of the membrane region 330 and that of the outer peripheral region 332 are formed to be flush or substantially flush in height with each other. At the back side of the outer peripheral region 332, the substrate 31 is supported on the support table 33. The central part of the support table 33 is open, and the membrane region 330 is located at this opening region.

In the membrane region 330, passage holes 25 (openings) through each of which a corresponding one of the multiple beams 20 passes are formed at positions each corresponding to each hole 22 in the shaping aperture array substrate 203 shown in FIG. 2. In other words, in the membrane region 330 of the substrate 31, there are formed a plurality of passage holes 25, in an array state, through each of which a corresponding one of the multiple electron beams 20 passes. Furthermore, in the membrane region 330 of the substrate 31, there are arranged a plurality of electrode pairs each composed of two electrodes being opposite to each other across a corresponding one of a plurality of passage holes 25. Specifically, in the membrane region 330, as shown in FIG. 3, each pair of a control electrode 24 and a counter electrode 26, (blanker: blanking deflector), for blanking deflection is arranged close to a corresponding passage hole 25 in a manner such that the electrodes 24 and 26 are opposite to each other across the passage hole 25 concerned. Furthermore, close to each passage hole 25 in the membrane region 330, inside the substrate 31, there is arranged a control circuit 41 (logic circuit) which applies a deflection voltage to the control electrode 24 for the passage hole 25 concerned. The counter electrode 26 for each beam is grounded.

In the control circuit 41, an amplifier (not shown) (an example of a switching circuit) is arranged. As an example of the amplifier, a CMOS (complementary MOS) inverter circuit is arranged. The CMOS inverter circuit is connected to a positive potential (Vdd: blanking potential: first potential) (e.g., 5 V) (the first potential) and to a ground potential (GND: the second potential). The output line (OUT) of the CMOS inverter circuit is connected to the control electrode 24. By contrast, the counter electrode 26 is applied with a ground potential. A plurality of control electrodes 24, each of which is applied with a blanking potential and a ground potential in a switchable manner, are arranged on the substrate 31 such that each control electrode 24 and the corresponding counter electrode 26 are opposite to each other across the passage hole 25 concerned in the plurality of passage holes 25.

As an input (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit becomes a positive potential (Vdd). Then, a corresponding one of the multiple beams 20 is deflected by an electric field due to a potential difference from the ground potential of the counter electrode 26, and controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding one of the multiple beams 20 is not deflected, and controlled to be in a beam ON condition by passing through the limiting aperture substrate 206.

A corresponding one of the multiple beams 20, passing through a corresponding passage hole, is deflected by a voltage independently applied to a pair of the control electrode 24 and the counter electrode 26. Blanking control is provided by this deflection. Specifically, a pair of the control electrode 24 and the counter electrode 26 individually provides blanking deflection of a corresponding beam of the multiple beams 20 by an electric potential switchable by the CMOS inverter circuit serving as a switching circuit corresponding to each pair. Thus, each of a plurality of blankers performs blanking deflection of a corresponding one of the multiple beams 20 having passed through a plurality of holes 22 (openings) in the shaping aperture array substrate 203.

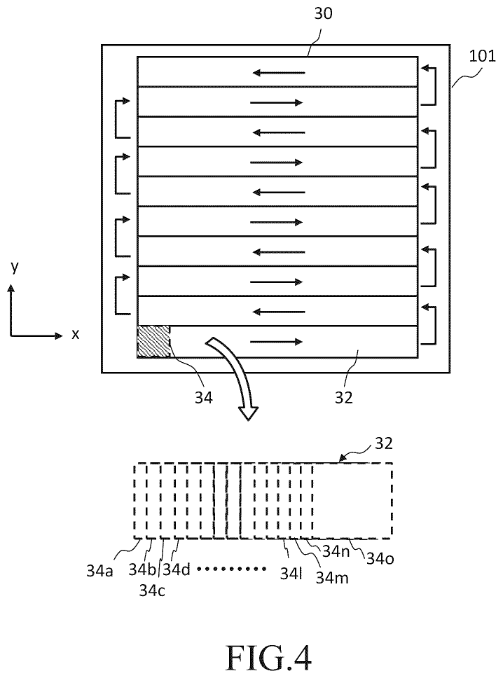

FIG. 4 is a conceptual diagram illustrating an example of a writing operation according to the first embodiment. As shown in FIG. 4, a writing region 30 of the target object 101 is virtually divided, for example, by a predetermined width in the y direction into a plurality of stripe regions 32 in a strip form. First, the XY stage 105 is moved to make an adjustment such that an irradiation region 34 which can be irradiated with one shot of the multiple beams 20 is located at the left end of the first stripe region 32 or at a position further left than the left end, and then writing is started. When writing the first stripe region 32, the writing proceeds relatively in the x direction by moving the XY stage 105 in the −x direction, for example. The XY stage 105 is moved, for example, continuously at a constant speed. After writing the first stripe region 32, the stage position is moved in the −y direction to make an adjustment such that the irradiation region 34 is located at the right end of the second stripe region 32 or at a position further right than the right end to be thus located relatively in the y direction. Then, by moving the XY stage 105 in the x direction, for example, writing proceeds in the −x direction.

That is, writing is performed while alternately changing the direction, such as performing writing in the x direction in the third stripe region 32, and in the −x direction in the fourth stripe region 32, thereby reducing the writing time. However, the writing operation is not limited to the writing while alternately changing the direction, and it is also preferable to perform writing in the same direction when writing each stripe region 32. Owing to one shot of multiple beams having been formed by passing through the holes 22 in the shaping aperture array substrate 203, a plurality of shot patterns maximally up to as many as the number of a plurality of holes 22 in the shaping aperture array substrate 203 are formed at a time. Furthermore, although FIG. 4 shows the case where writing is performed once for each stripe region 32, it is not limited thereto. It is also preferable to perform multiple writing which writes the same region multiple times. In performing the multiple writing, preferably, the stripe region 32 of each pass is set while shifting the position.

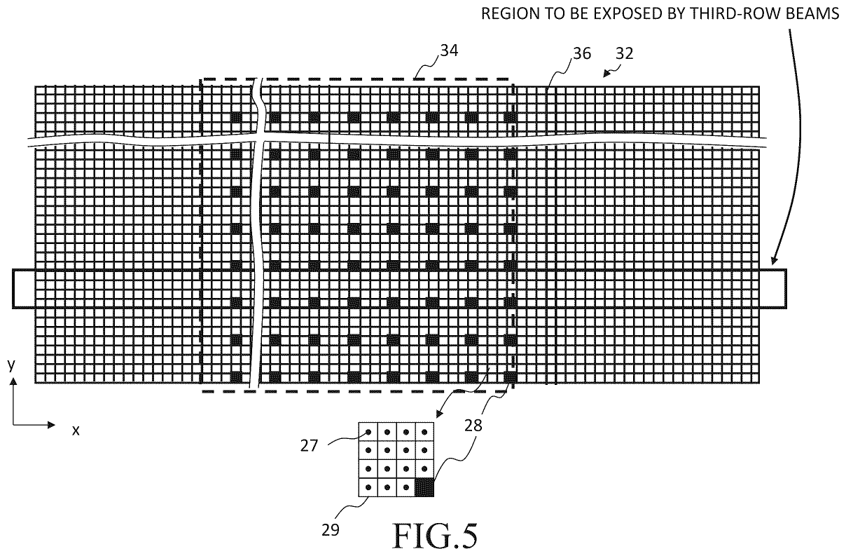

FIG. 5 is an illustration showing an example of an irradiation region of multiple beams and a pixel to be written (writing target pixel) according to the first embodiment. In FIG. 5, in the stripe region 32, there are set a plurality of control grids 27 (design grids) arranged in a grid form at the beam size pitch of the multiple beams 20 on the surface of the target object 101, for example. Preferably, the control grids 27 are arranged at a pitch of around 10 nm. The plurality of control grids 27 serve as design irradiation positions (irradiation positions in design) of the multiple beams 20. The arrangement pitch of the control grid 27 is not limited to the beam size, and may be any size that can be controlled as a deflection position of the deflector 209, regardless of beam size. Then, a plurality of pixels 36 are set by virtually dividing into meshes, each centering on each control grid 27, by the same size as that of the arrangement pitch of the control grid 27. Each pixel 36 serves as an irradiation unit region per beam of the multiple beams. FIG. 5 shows the case where the writing region of the target object 101 is divided, for example, in the y direction, into a plurality of stripe regions 32 by the width size being substantially the same as the size of the irradiation region 34 (writing field) which can be irradiated by one irradiation with the multiple beams 20 (beam array). The x-direction size of the irradiation region 34 can be defined by the value obtained by multiplying the x-direction beam pitch (pitch between beams) of the multiple beams 20 by the number of x-direction beams. The y-direction size of the irradiation region 34 can be defined by the value obtained by multiplying the y-direction beam pitch of the multiple beams 20 by the number of y-direction beams. The width of the stripe region 32 is not limited to this.

Preferably, the width of the stripe region 32 is n times (n being an integer of one or more) the size of the irradiation region 34. FIG. 5 shows the case where the multiple beams of 512×512 (rows×columns) are simplified to 8×8 (rows×columns). In the irradiation region 34, there are shown a plurality of pixels 28 (beam writing positions) which can be irradiated with one shot of the multiple beams 20. In other words, the pitch between adjacent pixels 28 is the pitch between beams of the design multiple beams. In the example of FIG. 5, one sub-irradiation region 29 is a region surrounded by beam pitches. In the case of FIG. 5, each sub-irradiation region 29 is composed of 4×4 pixels.

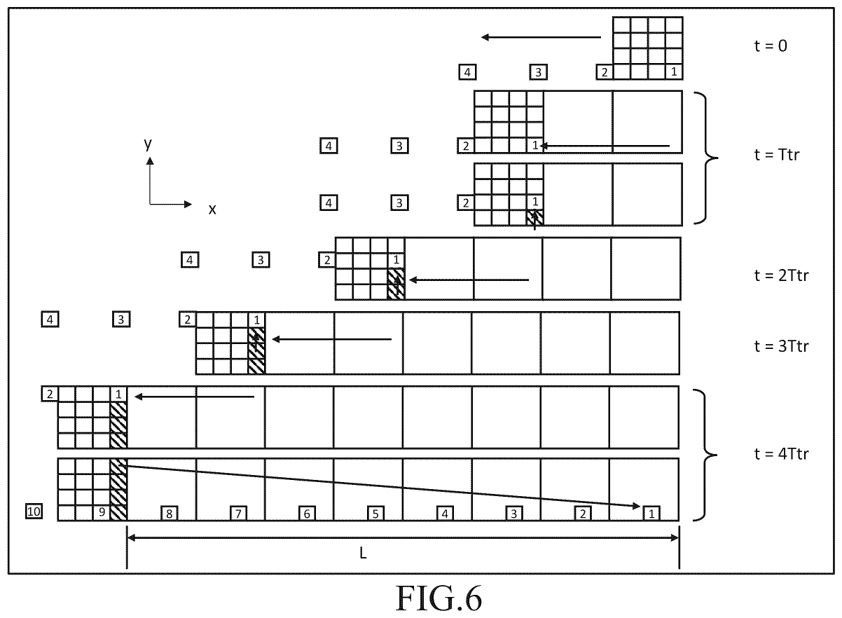

FIG. 6 is an illustration showing an example of a writing method of multiple beams according to the first embodiment. FIG. 6 shows a portion of the sub-irradiation region 29 to be written by each of beams at the coordinates (1, 3), (2, 3), (3, 3), . . . , (512, 3) of the y-direction k-th row in the multiple beams for writing the stripe region 32 shown in FIG. 5. In the example of FIG. 6, while the XY stage 105 moves the distance of eight beam pitches, four pixels are written (exposed), for example. In order that the relative position between the irradiation region 34 and the target object 101 may not deviate by the movement of the XY stage 105 while these four pixels are written (exposed), all of the multiple beams 20 are collectively deflected by the deflector 208. Thereby, the irradiation region 34 is made to follow the movement of the XY stage 105. In other words, tracking control is performed. In the case of FIG. 6, one tracking cycle is executed by writing (exposing) four pixels during moving the distance of eight beam pitches.

Specifically, in each shot, beam irradiation is performed during a writing time (irradiation time or exposure time) corresponding to each control grid 27 within the set-up maximum irradiation time. Specifically, each control grid 27 is irradiated with a corresponding ON beam in the multiple beams 20. Then, at each completion of the shot cycle time Ttr obtained by adding a settling time of the DAC amplifier to the maximum writing time, the irradiation position of each beam is moved to the next shot position by a collective deflection by the deflector 209.

In the case of FIG. 6, when four shots have been completed, the DAC amplifier unit 134 resets a beam deflection for tracking control. Thereby, the tracking position is returned to the tracking start position where the tracking control was started.

Writing of the pixels in the first column from the right of each sub-irradiation region 29 has been completed. Therefore, after resetting the tracking, in a next tracking cycle, the deflector 209 first performs deflection to adjust (shift) the irradiation position of each corresponding beam to the control grid 27 of the pixel in the bottom row and the second column from the right of each sub-irradiation region 29. By repeating such an operation, all the pixels are written. When the sub-irradiation region 29 is composed of n×n pixels, each n pixels are written by different beams by n-time tracking operations. Thereby, all of the pixels in one region of n×n pixels are written. With respect also to other regions each composed of n×n pixels in the irradiation region of the multiple beams, the same operation is executed at the same time so as to perform writing similarly.

Next, operations of the writing mechanism 150 of the writing apparatus 100 will be described. The electron beam 200 emitted from the electron gun 201 (emission source) illuminates the whole of the shaping aperture array substrate 203 by the illumination lens 202. A plurality of rectangular (including square) holes 22 (openings) have been formed in the shaping aperture array substrate 203. Then, the region including all of the plurality of holes 22 is irradiated with the electron beam 200. Portions of the electron beam 200 applied to the positions of the plurality of holes 22 individually pass through a corresponding hole of the plurality of holes 22 in the shaping aperture array substrate 203. Thereby, for example, a plurality of rectangular (including square) electron beams (multiple beams 20) are formed. The multiple beams 20 individually pass through corresponding blankers (the first deflector: individual blanking mechanism) of the blanking aperture array mechanism 204. Each blanker deflects (provides blanking deflection) the electron beam passing individually therethrough.

The multiple beams 20 having passed through the blanking aperture array mechanism 204 are reduced by the reducing lens 205, and travel toward the hole in the center of the limiting aperture substrate 206. Then, an electron beam in the multiple beams 20 which was deflected by the blanker of the blanking aperture array mechanism 204 deviates from the hole in the center of the limiting aperture substrate 206 and is blocked by the limiting aperture substrate 206. In contrast, an electron beam which was not deflected by the blanker of the blanking aperture array mechanism 204 passes through the hole in the center of the limiting aperture substrate 206 as shown in FIG. 1. Blanking control is provided by ON/OFF of an individual blanking mechanism so as to control ON/OFF of beams. Thus, the limiting aperture substrate 206 blocks each beam which was deflected to be in the OFF state by the individual blanking mechanism. Then, for each beam, one shot beam is formed by a beam which has been made during a period from becoming beam ON to becoming beam OFF and has passed through the limiting aperture substrate 206. The multiple beams 20 having passed through the limiting aperture substrate 206 are focused by the objective lens 207 so as to be a pattern image of a desired reduction ratio. Then, respective beams having passed through the limiting aperture substrate 206, namely the whole of the multiple beams 20 having passed, are collectively deflected in the same direction by the deflectors 208 and 209 in order to irradiate respective beam irradiation positions on the target object 101. Ideally, the multiple beams 20 irradiating at a time are aligned at the pitch obtained by multiplying the arrangement pitch of the plurality of holes 22 in the shaping aperture array substrate 203 by a desired reduction ratio described above.

As described above, a defective beam may be generated in the multiple beams. As the defective beam, exemplified are an excessive dose defective beam which delivers an excessive dose irradiation since controlling the beam dose is disabled, and an insufficient dose defective beam which delivers an insufficient dose irradiation since controlling the beam dose is disabled. An ON defective beam which is “always-ON”, and a portion of uncontrollable defective beam whose irradiation time is uncontrollable are included in the excessive dose defective beam. An OFF defective beam which is “always-OFF”, and a remaining of uncontrollable defective beam are included in the insufficient dose defective beam.

If a target object is not irradiated with a planned dose, because of a defective beam, a problem occurs in that a shape error of a pattern formed on the target object is generated. To solve this problem, conventionally, each pixel dose corresponding to a writing pattern to be written is calculated. Then, with respect to the dose of each pixel, an excessive or insufficient dose amount associated with (applied by) a defective beam is calculated. Then, a dose distribution ratio for distributing a calculated excessive or insufficient dose amount to peripheral beams is calculated, and, based on the distribution ratio, dose modulation for each pixel is performed. Such a correction method described above has been examined. However, data processing for correcting a defective beam takes time. For this reason, a problem may occur in that data generation cannot keep up with the speed of writing processing. Furthermore, when a writing pattern serving as a writing target is changed, it becomes necessary, in order to obtain the rate of distribution to peripheral beams, to restart from calculating each pixel dose corresponding to a writing pattern to be written. Thus, every time the writing pattern is changed, it has been necessary to restart, from the first, the data processing of obtaining the rate of distribution to peripheral beams.

With respect to defective beams other than an “always-OFF” beam, if the design dose corresponding to a writing pattern is not determined (obtained), it is unknown whether each of the doses of the defective beams is insufficient or excessive. When an excessive dose is corrected, doses of peripheral beams are to be reduced. Therefore, a pixel which has no pattern and whose design dose is zero cannot be used for defect correction because it is impossible to reduce the dose from the pixel. Obtaining a distribution ratio for distribution to peripheral beams cannot be accomplished without using a writing pattern. In contrast, with respect to an “always-OFF” defective beam in defective beams, since the dose to be applied is zero, doses of peripheral beams are to be increased when defect correction is performed. Therefore, even a pixel which has no pattern and whose design dose is zero can be used for defect correction. Accordingly, regardless of writing pattern, it is possible to independently obtain a distribution ratio used for distribution to peripheral beams.

According to the first embodiment, with respect to an “always-OFF” beam in defective beams, as preprocessing before starting writing processing, a distribution ratio used for distributing an insufficient dose to peripheral beams is obtained regardless of writing pattern. Then, defect correction data which defines a distribution ratio for each distribution destination of each pixel is generated beforehand. In actual writing processing, for each writing pattern, dose modulation of each pixel is performed using the generated defect correction data which is independent of the writing pattern. It will be specifically described.

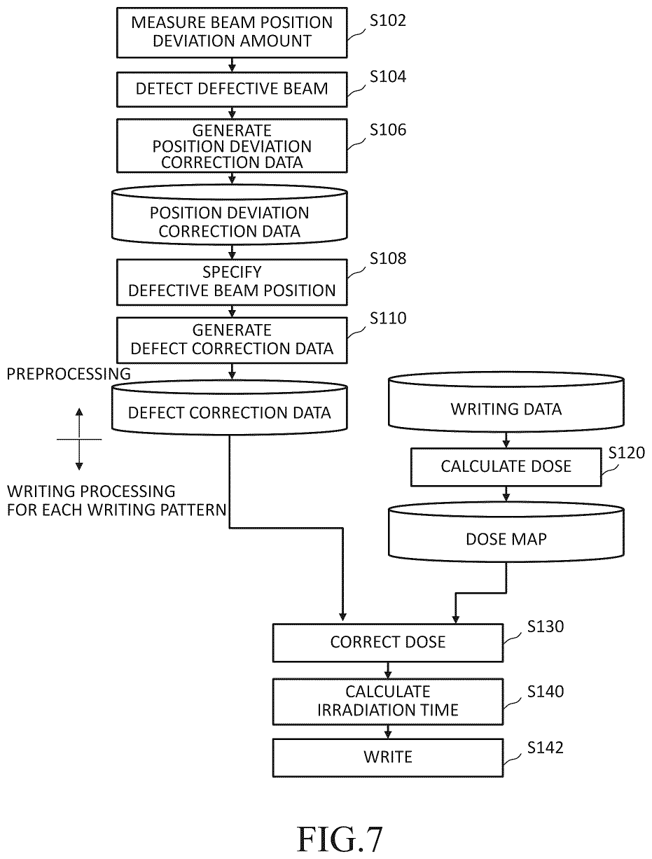

FIG. 7 is a flowchart showing an example of main steps of a writing method according to the first embodiment. In FIG. 7, the writing method of the first embodiment executes a series of steps: a beam position deviation amount measurement step (S102), a defective beam detection step (S104), a position deviation correction data generation step (S106), a defective beam position specifying step (S108), a defect correction data generation step (S110), a dose calculation step (S120), a dose correction step (S130), an irradiation time calculation step (S140), and a writing step (S142). Although, in the first embodiment, the case where correction of beam position deviation is performed in addition to correction of a defective beam is described, it is not limited thereto. In the case of not performing beam position deviation correction, the beam position deviation amount measurement step (S102) and the position deviation correction data generation step (S106) may be omitted.

The beam position deviation amount measurement step (S102), the defective beam detection step (S104), the position deviation correction data generation step (S106), the defective beam position specifying step (S108), and the defect correction data generation step (S110) are performed as preprocessing before starting writing processing.

In the beam position deviation amount measurement step (S102), the writing apparatus 100 measures the amount of position deviation of each beam irradiation position of the multiple beams 20 on the target object 101 surface, deviating from a corresponding control grid 27.

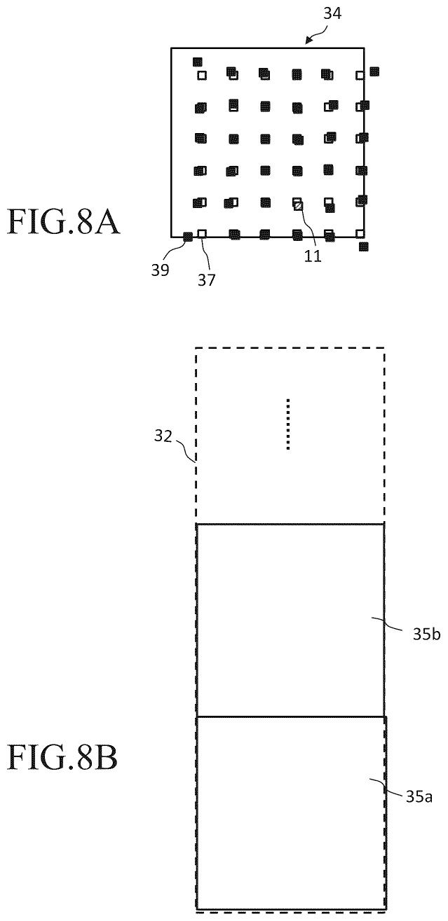

FIGS. 8A and 8B are illustrations each showing a beam position deviation and a position deviation periodicity according to the first embodiment. With regard to the multiple beams 20, as shown in FIG. 8A, distortion occurs in an exposure field due to the characteristics of the optical system, and therefore, because of the distortion and the like, an actual irradiation position 39 of each beam is deviated from an irradiation position 37 being an irradiation position of an ideal grid. Then, according to the first embodiment, the amount of position deviation of the actual irradiation position 39 of each beam is measured. Specifically, an evaluation substrate coated with resist is irradiated with the multiple beams 20, and is developed in order to generate a resist pattern. Then, the position of the generated resist pattern is measured by a position measuring instrument, thereby measuring a position deviation amount of each beam. If it is difficult to measure the size of the resist pattern at the irradiation position of each beam by a position measuring instrument since the shot size of the beam concerned is small, a figure pattern (e.g., rectangular pattern) of a measurable size by the position measuring instrument is to be written. Then, edge positions of the both sides (right and left sides or upper and lower sides) of the figure pattern (resist pattern) are measured to measure a position deviation amount of a target beam based on a difference between the intermediate position of the both edges and the intermediate position of a design figure pattern (figure pattern in design). Obtained position deviation amount data on each beam irradiation position is input to the writing apparatus 100, and stored in the storage device 144. Furthermore, in the multiple beam writing, since writing proceeds while shifting the irradiation region 34 in the stripe region 32, the position of the irradiation region 34 moves one by one, such as from the irradiation region 34a to 340, during writing of the stripe region 32 as shown in the lower part of FIG. 4 according to the writing sequence explained in FIG. 6, for example. Then, every time the irradiation region 34 is moved, periodicity occurs in position deviation of each beam. Alternatively, if in the case of the writing sequence where each beam irradiates all of the pixels 36 in the sub-irradiation region 29 corresponding to the beam concerned, as shown in FIG. 8B, periodicity occurs in position deviation of each beam at least in each unit region 35 (35a, 35b, . . . ) of the same size as the irradiation region 34. Therefore, when the position deviation amount of each beam for one irradiation region 34 in the beam array is measured, the measurement result can also be used for other regions. In other words, it is sufficient to measure a position deviation amount at each pixel 36 in the sub-irradiation region 29 corresponding to each beam.

The beam position deviation map generation unit 50 first generates a beam position deviation amount map (1) which defines a position deviation amount of each beam for each pixel 36 in a beam array unit, in other words, in one rectangular unit region 35 (an example of a unit region), on the target object surface, corresponding to the irradiation region 34. The rectangular unit region 35 corresponds, on the target object surface, to the irradiation region 34 of the multiple beams 20 which is configured by combining each design sub-irradiation region 29 (sub region) surrounded by a target beam and a plurality of beams adjacent to the target beam, with respect to each beam of the multiple beams 20. Although the unit region is here rectangular since the multiple beams 20 are arrayed in a square grid pattern, the shape of the unit region may be varied in accordance with the arrangement shape of the multiple beams 20. Specifically, the beam position deviation map generation unit 50 reads position deviation amount data on the irradiation position of each beam from the storage device 144, and generates the beam position deviation amount map (1) by using the data as a map value. Which beam in all of the multiple beams 20 irradiates the control grid 27 of each pixel 36 in one rectangular unit region 35, on the target object surface, corresponding to the irradiation region 34 of the whole of the multiple beams 20 is determined based on the writing sequence as described with reference to FIG. 6, for example. Therefore, the beam position deviation map generation unit 50 specifies, for each control grid 27 of each pixel 36 in one unit region 35, a beam to irradiate the control grid 27 concerned according to the writing sequence, and calculates the position deviation amount of the beam concerned. The generated beam position deviation amount map (1) is stored in the storage device 144.

In the defective beam detection step (S104), the detection unit 54 detects a defective beam in the multiple beams 20. The ON defective beam being “always-ON” performs all the time an irradiation of the maximum irradiation time, which is maximum in one shot, regardless of control dose. Furthermore, it continues the irradiation also during moving from one pixel to another. The OFF defective beam being “always-OFF” is all the time “beam OFF” regardless of control dose. Specifically, under the control of the writing control unit 74, the writing mechanism 150 controls each of the multiple beams 20 to be “beam ON” one by one by the blanking aperture array mechanism 204, and the other beams, except for the “ON” beams, to be “OFF”. In such a state, if there is a beam whose current is not detected by the Faraday cup 106, the beam is detected as an OFF defective beam. Then, the control is switched from this state to a state in which a target beam to be detected is an “OFF” beam. At this time, notwithstanding that the target beam to be detected has been switched from an “ON” beam to an “OFF” beam, if there is a beam whose current is detected by the Faraday cup 106 all the time, the beam is detected as an ON defective beam. After the target beam to be detected has been switched from an “ON” beam to an “OFF” beam, if there is a beam whose current is detected by the Faraday cup 106 only during a predetermined period, the beam is detected as an uncontrollable defective beam. By checking each of the multiple beams 20 in order by the same method, it is possible to detect whether there is a defective beam or not, what kind of a defective beam is, and where a defective beam is located. Although the case of detecting also a defective beam other than an OFF defective beam is here described, it is also acceptable to detect only an OFF defective beam being “always-OFF”. Information on a detected defective beam is stored in the storage device 144.

In the position deviation correction data generation step (S106), the position deviation correction data generation unit 52 generates position deviation correction data for correcting an individual position deviation of each irradiation position of the multiple beams 20.

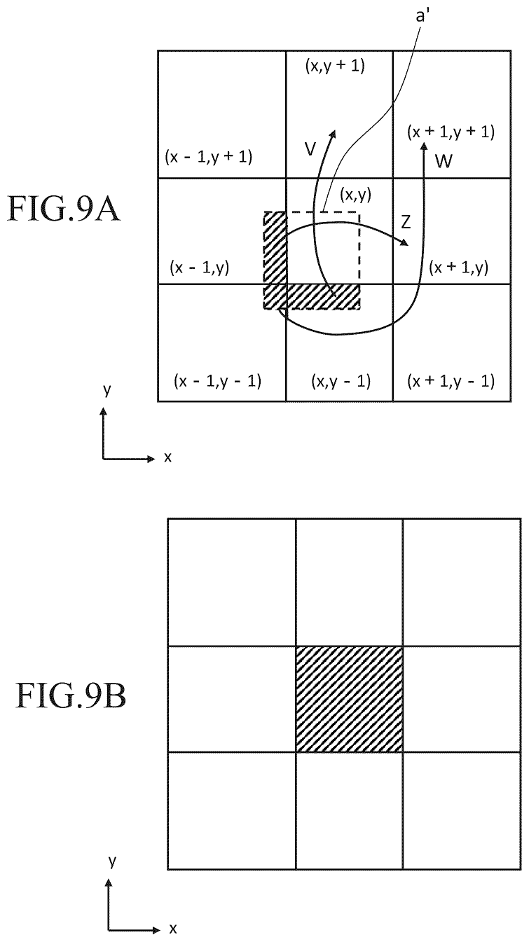

FIGS. 9A and 9B are illustrations showing an example of a method for correcting a position deviation according to the first embodiment. FIG. 9A shows the case where the position of a beam “a′” irradiating the pixel at coordinates (x, y) deviates in the −x and −y directions. In order to correct the deviated position of the pattern formed by the beam “a′” with such a position deviation to the position corresponding to the pixel at coordinates (x, y) as shown in FIG. 9B, correction can be accomplished by distributing (for sharing) the dose corresponding to the deviated position to pixels located opposite to the direction of peripheral deviated pixels. In the example of FIG. 9A, the dose corresponding to the position deviated to the pixel at coordinates (x, y−1) should be distributed to the pixel at coordinates (x, y+1). The dose corresponding to the position deviated to the pixel at coordinates (x−1, y) should be distributed to the pixel at coordinates (x+1, y). The dose corresponding to the position deviated to the pixel at coordinates (x−1, y−1) should be distributed to the pixel at coordinates (x+1, y+1).

According to the first embodiment, in proportion to a position deviation amount of a beam, a distribution amount for correcting the position deviation is calculated in order to distribute a dose to a beam for at least one of peripheral pixels. In proportion to a ratio of an area deviated due to position deviation of a beam applied to the pixel concerned, the position deviation correction data generation unit 52 calculates a modulation rate of a beam applied to the pixel concerned, and a modulation rate of a beam applied to at least one of peripheral pixels surrounding the pixel concerned. Specifically, for each of peripheral pixels where a portion of a beam is overlapped because the beam has deviated from the pixel concerned, a ratio is calculated by dividing a deviated area (area of beam overlapping portion) by the beam area, where the ratio is calculated as a distribution amount (beam modulation rate) to be distributed to a pixel located opposite, with respect to the pixel concerned, to the pixel of the overlapped beam.

In the case of FIG. 9A, the area ratio of the portion deviated to the pixel at coordinates (x, y−1) can be calculated by (“x direction beam size”−“−x direction deviation amount”)×“y direction deviation amount”/(“x direction beam size”×“y direction beam size”). Therefore, a distribution amount (beam modulation rate) V to be distributed for correction to the pixel at coordinates (x, y+1) can be calculated by (“x direction beam size”−“−x direction deviation amount”)×“y direction deviation amount”/(“x direction beam size”×“y direction beam size”).

Also, in the case of FIG. 9A, the area ratio of the portion deviated to the pixel at coordinates (x−1, y−1) can be calculated by “−x direction deviation amount” x“−y direction deviation amount”/(“x direction beam size”×“y direction beam size”). Therefore, a distribution amount (beam modulation rate) W to be distributed for correction to the pixel at coordinates (x+1, y+1) can be calculated by “−x direction deviation amount”×“−y direction deviation amount”/(“x direction beam size”×“y direction beam size”).

Also, in the case of FIG. 9A, the area ratio of the portion deviated to the pixel at coordinates (x−1, y) can be calculated by “−x direction deviation amount”×(“y direction beam size”−“−y direction deviation amount”)/(“x direction beam size”×“y direction beam size”). Therefore, a distribution amount (beam modulation rate) Z to be distributed for correction to the pixel at coordinates (x+1, y) can be calculated by “−x direction deviation amount”×(“y direction beam size”−“−y direction deviation amount)”/(“x direction beam size”×“y direction beam size”).

Consequently, the modulation rate U of the beam irradiating the pixel at coordinates (x, y), which remains without having been distributed, can be calculated by 1−V−W−Z.

In this way, for each beam array unit, that is, for each pixel 36 in one rectangular unit region 35, on the target object surface, corresponding to the irradiation region 34, the modulation rate of a beam applied to the pixel concerned, and the modulation rate of a beam applied to at least one peripheral pixel serving as a distribution destination are calculated. Then, the position deviation correction data generation unit 52 generates, for each pixel 36, position deviation correction data in which the modulation rate of a beam applied to the pixel concerned and the modulation rate of a beam applied to at least one of peripheral pixels serving as distribution destinations are defined. The position deviation correction data is generated for one rectangular unit region 35, on the target object surface, corresponding to the irradiation region 34. The generated position deviation correction data is stored in the storage device 144.

In the defective beam position specification step (S108), the specification unit 55 specifies a pixel irradiated with an “always-OFF” defective beam in defective beams, for each beam array unit, that is, for each pixel 36 in one rectangular unit region 35, on the target object surface, corresponding to the irradiation region 34. Which beam irradiates the control grid 27 of each pixel 36 in the rectangular unit region 35 is determined based on the writing sequence as described above.

In the defect correction data generation step (S110), regardless of writing pattern to be written, the defect correction data generation unit 56 generates defect correction data which defines a dose modulation rate for performing correction by distributing the dose at a position irradiated with an always-OFF defective beam in the multiple beams 20 to at least one of other pixels, using a dose distribution in which each beam array unit, in other words, each pixel 36 in one rectangular unit region 35, on the target object surface corresponding to the irradiation region 34 is defined by a uniform dose.

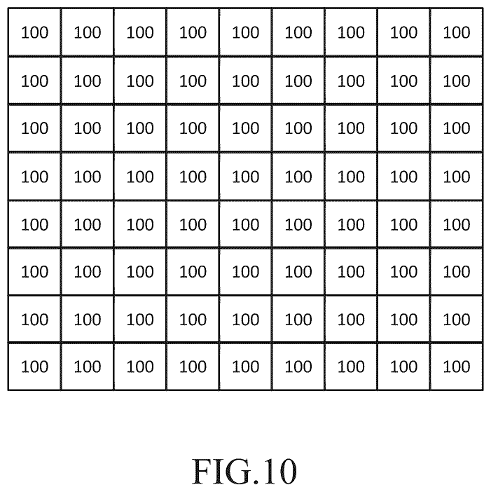

FIG. 10 is an illustration showing an example of a dose map for a rectangular unit region for defect correction according to the first embodiment. As shown in FIG. 10, it is preferable to use the dose of 100% with respect to the reference dose, as a dose for each pixel. In other words, it is assumed the case where the whole of the rectangular unit region 35 is so called a solid pattern (or “beta pattern”). Since the whole of the rectangular unit region 35 is so called a solid pattern, it does not depend on a writing pattern to be written actually.

In the case of FIG. 6, the XY stage 105 moves thirty-two beam pitches (=four times×eight beam pitches) in the −x direction by four tracking operations. Thus, during the moving of thirty-two beam pitches, one writing processing is performed/completed. With this configuration, if a beam array unit, in other words, the whole of one rectangular unit region 35, on the target object surface, corresponding to the irradiation region 34 is written by the multiple beams of 512×512 beams, multiple writing (multiplicity=16) is performed for each pixel 36 by writing processing (pass) of sixteen times (=512/32). If it is written by the multiple beams 20 of 32×32 beams, one writing processing (pass) is performed for each pixel. If the XY stage 105 performs continuous movement by repeating, for example, four times, multiple writing (multiplicity=4) by four-time writing processing (pass) is performed for each pixel 36. According to the first embodiment, not each writing processing of multiple writing, but the number of times of movement of the stage is expressed as one pass.

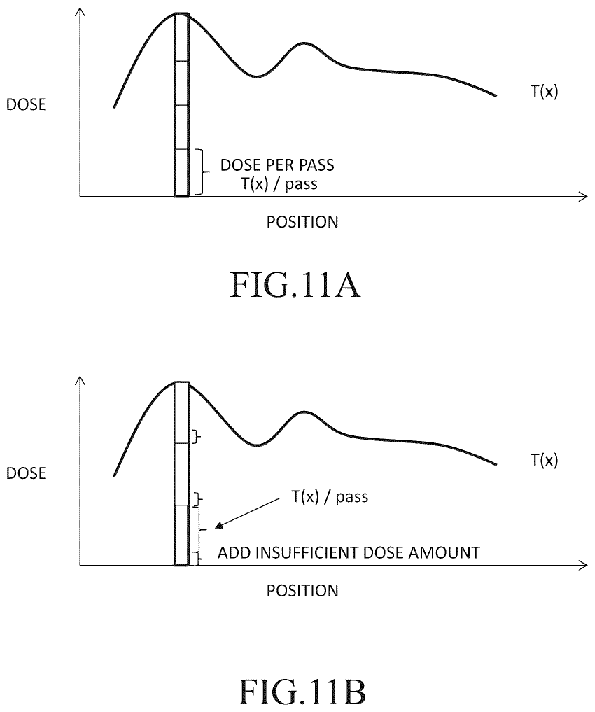

FIGS. 11A and 11B are illustrations each showing an example of a method for correcting a defect by multiple writing according to the first embodiment. FIGS. 11A and 11B show the case of performing multiple writing by four-time writing processing (pass). Each pixel is irradiated with four different beams, for example. The dose T(x) to such a pixel is applied as ¼ each for each pass. Therefore, the pixel which is not associated with a defective beam is irradiated with the dose of T(x)/pass each time as shown in FIG. 11A. The pixel which is associated with a defective beam is irradiated with the defective beam once out of four time irradiation. No beam is applied in the pass associated with the defective beam, thereby resulting in insufficiency of the dose equivalent to one-time dose. Then, when a writing pattern is written on the target object by multiple writing, the defect correction data generation unit 56 generates defect correction data so that the dose at the position associated with (irradiated with) a defective beam, applied in one of a plurality of passes of multiple writing, may be corrected in the other passes. For example, as shown in FIG. 11B, defect correction data is generated so that a distribution dose (being equivalent to the insufficiency), which is obtained by dividing a one-time dose by the number of the other passes, can be uniformly added to the other passes. In the case of FIG. 11B, the amount equivalent to 25% of the dose is distributed by 33% each. The distribution method is not limited to the even distribution. The distribution can be performed unevenly concentrating to some passes. If the distribution is performed unevenly, there is a case of the dose at some passes becoming too large. In that case, the maximum irradiation time is increased, thereby leading to an increase in the writing time. Therefore, it is preferable to carry out an even distribution which performs addition equally to other passes, and thus, the maximum irradiation time increase can be prevented.

In defect correction data, with respect to a pixel associated with a defective beam, an own dose modulation rate of 0% and a dose modulation rate for at least one pass serving as a distribution destination are defined. With respect to each of other pixels, a dose modulation rate of 100% being solid data is defined. Preferably, defect correction data is generated for each pass. Information on a pixel associated with a defective beam is shared among passes.

As described above, in the case where position deviation correction data is generated, the defect correction data generation unit 56 inputs the position deviation correction data for correcting an individual position deviation of each irradiation position of the multiple beams, and generates defect correction data by using the position deviation correction data. Therefore, with respect to a pixel associated with a defective beam, an own dose modulation rate of 0% and a dose modulation rate for at least one pass serving as a distribution destination are defined. Then, the dose modulation rate for a pass serving as a distribution destination is defined as a value obtained by further multiplying each dose modulation rate for the target pixel defined in the position deviation correction data. With respect to each of other pixels, a dose modulation rate obtained by multiplying each dose modulation rate for the target pixel defined in the position deviation correction data by 100% is defined.

Defect correction is not limited to performing distribution to other passes. For example, the defect correction data generation unit 56 generates defect correction data such that the dose at the position associated with a defective beam is corrected by at least one of peripheral beams which irradiate positions on the periphery of the position associated with the defective beam.

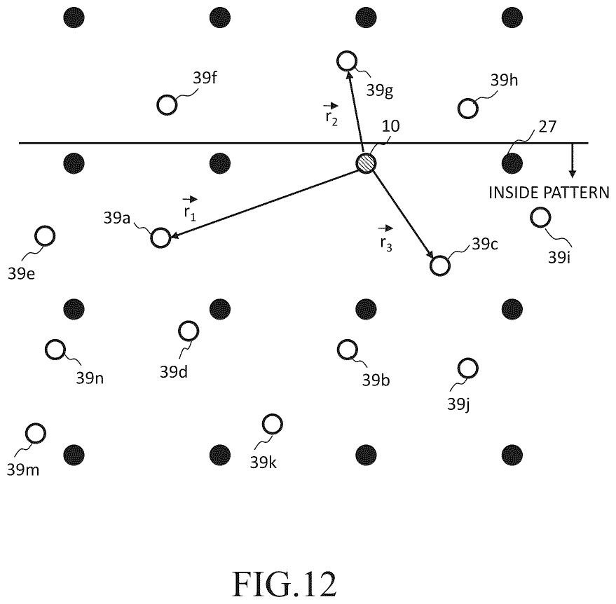

FIG. 12 is an illustration showing an example of a method for correcting a defect by using peripheral pixels according to the first embodiment. The defect correction data generation unit 56 distributes the dose at the position associated with a defective beam applied to at least one, for example, three or more peripheral pixels on the periphery of a control grid 10 of a pixel associated with the defective beam. In the case of FIG. 12, it is distributed to a peripheral pixel of an irradiation position 39a, a peripheral pixel of an irradiation position 39c, and a peripheral pixel of an irradiation position of 39g. It is preferable to use three or more irradiation positions surrounding the control grid 10 of the pixel associated with a defective beam. According to the first embodiment, preferably, a distribution ratio is determined such that the position of the gravity center of a plurality of distribution ratios (dose modulation rates) to be distributed is located at the position of the control grid 10 of the pixel associated with the defective beam. In that case, the distribution ratio is determined depending on a distance ri from the control grid 10 to the irradiation position of a peripheral beam. i indicates an index of a target peripheral beam in N peripheral beams. Each distribution ratio δdi can be defined by the following equation (1) using a 100% dose A and a distance ri.

$$\begin{matrix}[ Equation 1 ] & \\ δ {d}_{i} = Δ \cdot \frac{1}{{r}_{i}} / \sum \frac{1}{{r}_{i}} & ( 1 )\end{matrix}$$

As shown in FIG. 12, there may be a case where the irradiation position 39g being a distribution destination is located outside of the pattern. If the dose distribution in accordance with a writing pattern has been previously generated, it can be known whether the irradiation position of each pixel is located inside a pattern or outside the pattern. With respect to a pixel whose irradiation position is located outside the pattern, since its dose in accordance with a writing pattern is zero, an adjustment can be made such that the dose to be distributed for defect correction is increased. If deviation of the position of the gravity center is permissible, a distribution adjustment can be made such that, for example, the dose distribution ratio of 5% is for each of two pixels inside the pattern, and that of 80% is for one pixel outside the pattern. Thereby, it can be prevented that a pixel finally has a too large dose. However, in the first embodiment, since defect correction is performed regardless of writing pattern, it is unknown, at the time of calculating a distribution ratio for defect correction, whether the irradiation position of a distribution destination is inside a pattern or outside the pattern. Therefore, making an adjustment of the distribution ratio which depends on being inside or outside the pattern is difficult. Then, preferably, the upper limit is set for the distribution ratio. For example, preferably, the upper limit is set to about 40%. Furthermore, it is preferable that the maximum value of the total value (total modulation rate) between the dose modulation rate, for each pixel, for correcting a position deviation of the pixel concerned and the dose modulation rate distributed from another pixel is set as the upper limit. Thereby, it can be prevented that a pixel finally has a too large dose. Thus, the increase in the maximum irradiation time can be suppressed, which consequently leads to reduction of the writing time.

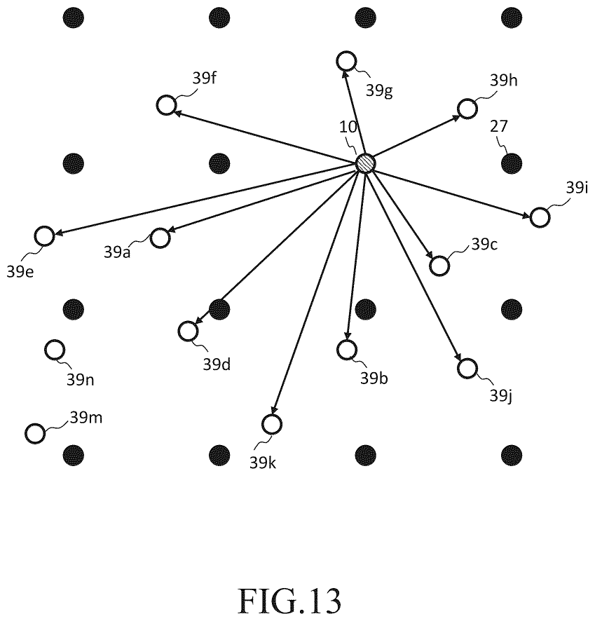

FIG. 13 is an illustration showing another example of the method for correcting a defect by using peripheral pixels according to the first embodiment. If the distribution ratio of a distribution destination exceeds the upper limit having been set, it is preferable to increase the number of distribution destinations as shown in FIG. 13. FIG. 13 shows the case of distributing to eleven pixels.

Furthermore, in the case where deviation of the gravity center position is not taken into consideration, although which degrades the accuracy, the distribution ratio od may be determined by the equation (2) of simply dividing 100% dose Δ by N being the number of distribution destinations.

$$\begin{matrix}[ Equation 2 ] & \\ δ d = Δ / N & ( 2 )\end{matrix}$$

In defect correction data, with respect to a pixel associated with a defective beam, an own dose modulation rate of 0% and a distribution ratio (dose modulation rate) for at least one or more pixels serving as distribution destinations are defined. With respect to each of other pixels, a dose modulation rate of 100% being solid data is defined.

As described above, in the case where position deviation correction data is generated, the defect correction data generation unit 56 inputs position deviation correction data for correcting an individual position deviation of each irradiation position of the multiple beams, and generates defect correction data by using the position deviation correction data. Therefore, with respect to a pixel associated with a defective beam, an own dose modulation rate of 0% and a dose modulation rate for at least one, for example, three or more pixels serving as distribution destinations are defined. At this stage, it is preferable that the gravity center position of the dose modulation rate of a distribution destination, for which a position deviation has been taken into consideration, is matched with the position of the pixel associated with a defective beam. With respect to each of other pixels, a dose modulation rate obtained by multiplying each dose modulation rate for the target pixel defined in the position deviation correction data by 100% is defined.

The generated defect correction data is stored in the storage device 144. The defect correction data may be generated in the state where, as described above, the contents of position deviation correction data has been considered.

Alternatively, defect correction data and position deviation correction data may be independently and separately stored in the storage device 144.

Thus, as preprocessing before starting writing processing, defect correction data (and position deviation correction data), being independent of a writing pattern, is/are generated. Next, writing processing for each writing pattern is performed.

Then, comparison is performed between the maximum (1) of the total value (total modulation rate) obtained by adding up the dose modulation rate of the pixel concerned, which is for correcting a position deviation of each pixel, and the dose modulation rate distributed from another pixel, and the maximum (2) of the distributed dose modulation rate of each pixel for correcting a defect. After the comparison, the lager one of (1) and (2) is determined as a value (3). If the reference value (4) of an individual dose in accordance with the writing pattern is known, the dose actually applied to each pixel is not larger than a multiplied value of ((3)×(4)). Then, regarding the multiplied value as the maximum dose ((3)×(4)), it is possible to obtain the maximum irradiation time by dividing the maximum dose by a current density. If dose modulation, such as proximity effect correction, is not performed, the base dose Dbase can be used as the reference value (4) of an individual dose. When dose modulation, such as proximity effect correction, is performed, a value obtained by multiplying the maximum of the rate of dose modulation, such as proximity effect correction, by the base dose Dbase can be used as the reference value (4) of an individual dose.

In the dose calculation step (S120), the dose map generation unit 62 (dose calculation unit) calculates, for each writing pattern, an individual dose of each pixel 36 on the target object 101 in accordance with the writing pattern concerned. Specifically, it operates as follows: First, the rasterization unit 60 reads writing data from the storage device 140, and calculates, for each pixel 36, the pattern area density ρ′ of the pixel 36 concerned. This processing is performed for each stripe region 32, for example.

Next, the dose map generation unit 62, first, virtually divides the writing region (e.g., in this case, stripe region 32) into a plurality of proximity mesh regions (mesh regions for proximity effect correction calculation) by a predetermined size. The size of the proximity mesh region is preferably set to be about 1/10 of the influence range of the proximity effect, such as about 1 μm. The dose map generation unit 62 reads writing data from the storage device 140, and calculates, for each proximity mesh region, a pattern area density ρ of a pattern arranged in the proximity mesh region concerned.

Next, the dose map generation unit 62 calculates, for each proximity mesh region, a proximity effect correction irradiation coefficient Dp(x) (correction dose) for correcting a proximity effect. An unknown proximity effect correction irradiation coefficient Dp(x) can be defined by a threshold value model for proximity effect correction, which is the same as the one used in a conventional method, where a backscatter coefficient η, a dose threshold value Dth of a threshold value model, a pattern area density ρ, and a distribution function g(x) are used.

Next, the dose map generation unit 62 calculates, for each pixel 36, an incident dose D(x) (amount of dose) with which the pixel 36 concerned is irradiated. The incident dose D(x) can be calculated, for example, by multiplying a preset base dose Dbase by the proximity effect correction irradiation coefficient Dp and the pattern area density ρ′. The base dose Dbase can be defined by Dth/(½+η), for example. Thereby, it is possible to obtain an originally desired incident dose D(x), for which a proximity effect has been corrected, based on layout of a plurality of figure patterns defined by the writing data.

Then, the dose map generation unit 62 generates a dose map in which an incident dose D(x) for each pixel 36 is defined per stripe unit. The incident dose D(x) for each pixel 36 is a designed planned incident dose D(x) to be applied to the control grid 27 of the pixel 36 concerned. In other words, the dose map generation unit 52 generates a dose map in which the incident dose D(x) for each control grid 27 is defined per stripe unit. The generated dose map is stored in the storage device 144, for example.

In the dose correction step (S130), the dose correction unit 64 reads, for each writing pattern, defect correction data from the storage device 144, performs a dose distribution using a value obtained by multiplying an individual dose at each position on the target object by the dose modulation rate defined in the read defect correction data, in order to correct the individual dose at each position on the target object according to the writing pattern concerned, and obtains the corrected dose.

Specifically, the dose correction unit 64, fist, repeatedly allocates the rectangular unit region 35 to the stripe region 32 according to the writing sequence. Thereby, it is possible to identify which beam irradiates each pixel 36 in the stripe region 32.

The dose correction unit 64 calculates, for each pixel, a value by multiplying an individual dose of each pixel in accordance with a writing pattern by the dose modulation rate of the pixel concerned defined in defect correction data. Furthermore, the dose correction unit 64 calculates, for each pixel, a value by multiplying an individual dose of each pixel in accordance with a writing pattern by the dose modulation rate for a pixel serving as a distribution destination defined in defect correction data, and distributes the calculated value to the pixel being a distribution destination. Next, the dose correction unit 64 adds up, for each pixel 36, the dose obtained by multiplied by the dose modulation rate of the pixel concerned, and the dose having been distributed. With respect to a pixel associated with a defective beam, if a dose distributed from another pixel exists, the dose after the addition is not zero. In that case, with respect to the pixel associated with the defective beam, a value is obtained by multiplying the dose after the addition by the dose modulation rate (0%) of the pixel concerned defined in the defect correction data. At the stage of generating defect correction data, it is preferable that a defective beam has previously been removed from distribution destinations of doses.

In the case where defect correction data and position deviation correction data are independently and separately stored, first, a value is obtained by multiplying an individual dose of each pixel in accordance with a writing pattern by the dose modulation rate of the pixel concerned defined in position deviation correction data. Furthermore, the dose correction unit 64 calculates, for each pixel, a value by multiplying an individual dose of the pixel concerned by the dose modulation rate for a pixel serving as a distribution destination defined in the defect correction data, and distributes the calculated value to the pixel being the distribution destination. Then, the dose correction unit 64 adds up, for each pixel 36, the dose obtained by multiplied by the dose modulation rate of the pixel concerned, and the dose having been distributed. Next, a value is obtained by multiplying the individual added-up dose of each pixel by the dose modulation rate of the pixel concerned defined in the defect correction data. Furthermore, the dose correction unit 64 calculates, for each pixel, a value by multiplying the individual added-up dose of the pixel concerned by the dose modulation rate for a pixel serving as a distribution destination defined in the defect correction data, and distributes the calculated value to the pixel being a distribution destination. Then, the dose correction unit 64 adds up, for each pixel 36, the dose obtained by multiplied by the dose modulation rate of the pixel concerned and the dose having been distributed. It is preferable to previously combine defect correction data and position deviation correction data, and collectively perform defect correction and position deviation correction all at once.

In the flowchart shown in FIG. 7, correction is not performed for a defective beam other than an “always-OFF” defective beam. However, it is not limited thereto. Correction may further be performed on an excessive dose due to an excessive dose defective beam such as an “always-ON” defective beam. The method for correcting an excessive dose may be the same as the conventional one.

In the irradiation time calculation step (S140), the irradiation time calculation unit 72 calculates an irradiation time t corresponding to the dose of each pixel for which beam position deviation has been corrected and an insufficient dose due to a defective beam has also been corrected. The irradiation time t can be obtained by dividing the dose D by a current density J. The irradiation time t of each pixel 36 (control grid 27) is calculated as a value within the maximum irradiation time Ttr which is the maximum for irradiation with one shot of the multiple beams 20. The irradiation time t of each pixel 36 (control grid 27) is converted to gray scale value data of 0 to 1023 gray scale levels in which the maximum irradiation time Ttr is, for example, 1023 gray scale levels (10 bits). The gray scaled irradiation time data is stored in the storage device 142.

In the writing step (S142), first, the writing control unit 74 rearranges irradiation time data in the order of shot in accordance with the writing sequence. Then, the irradiation time data is transmitted to the deflection control circuit 130 in the order of shot. The deflection control circuit 130 outputs a blanking control signal to the blanking aperture array mechanism 204 in the order of shot, and deflection control signals to the DAC amplifier units 132 and 134 in the order of shot. The writing mechanism 150 writes a pattern on the target object 101 by using the multiple beams 20 with the dose having been corrected.

As described above, according to the first embodiment, defect correction data (and position deviation correction data), being independent of a writing pattern, is/are previously generated before starting the writing processing. Then, using the defect correction data (and the position deviation correction data), an individual dose of each pixel in accordance with a writing pattern is corrected for each writing pattern. Even if the writing pattern changes, it is possible to use the defect correction data (and the position deviation correction data) which has/have already been generated. Therefore, there is no need of regenerating the defect correction data (and the position deviation correction data) whenever the writing pattern changes. Thus, the data processing time in the writing processing can be reduced.

Accordingly, according to the first embodiment, it is possible to avoid that data processing for correcting a defective beam cannot keep up with the speed of writing processing in multiple beam writing.

Embodiments have been explained referring to specific examples described above. However, the present invention is not limited to these specific examples. The above examples describe the case where each beam of the multiple beams 20 individually controls the irradiation time within the maximum irradiation time Ttr for one shot. However, it is not limited thereto. For example, the maximum irradiation time Ttr for one shot is divided into a plurality of sub-shots each having a different irradiation time. Then, for each beam, a combination of sub-shots is selected from the plurality of sub-shots in order that the combination may become the irradiation time for one shot. It is also preferable to control the irradiation time for one shot of each beam by continuously applying selected sub-shots using the same beam to the same pixel.

While the case of inputting a 10-bit control signal for controlling each control circuit 41 has been described above, the number of bits may be suitably set. For example, a 2-bit (or any one of 3-bit to 9-bit) control signal may be used. Alternatively, a control signal of 11 bits or more may be used.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Any multiple charged particle beam writing apparatus and multiple charged particle beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multiple charged particle beam writing apparatus comprising:
a beam forming mechanism configured to form multiple charged particle beams;
a defect correction data generation circuit configured to generate defect correction data which defines a dose modulation rate for performing correction by distributing a dose at a position associated with a defective beam, being always-OFF, in the multiple charged particle beams to at least one of other pixels, using a dose distribution in which each position in a unit region on a target object, corresponding to an irradiation region of a whole of the multiple charged particle beams, is defined by a uniform dose, regardless of writing pattern;
a storage device configured to store the defect correction data;
a dose calculation circuit configured to calculate, for each writing pattern, an individual dose at each position on the target object, in accordance with a writing pattern concerned;
a dose correction circuit configured to read, for the each writing pattern, the defect correction data from the storage device, to correct the individual dose at the each position on the target object in accordance with the writing pattern concerned by performing a dose distribution using a value obtained by multiplying the individual dose at the each position on the target object by the dose modulation rate defined in the defect correction data having been read, and to obtain a corrected dose; and
a writing mechanism configured to write the writing pattern on the target object by using the multiple charged particle beams with the corrected dose.

2. The apparatus according to claim 1, wherein the defect correction data generation circuit inputs position deviation correction data for correcting an individual position deviation at each irradiation position of the multiple charged particle beams, and generates the defect correction data by further using the position deviation correction data.

3. The apparatus according to claim 1, wherein
the writing pattern is written on the target object by multiple writing, and
the defect correction data generation circuit generates the defect correction data so that correction of the dose at the position associated with the defective beam, performed in one of a plurality of passes of the multiple writing, is to be executed in at least one of other passes of the plurality of passes.

4. The apparatus according to claim 1, wherein the defect correction data generation circuit generates the defect correction data such that correction of the dose at the position associated with the defective beam is performed by at least one of peripheral beams which irradiate positions on a periphery of the position associated with the defective beam.

5. The apparatus according to claim 2 further comprising:
a position deviation correction data generation circuit configured to generate the position deviation correction data for correcting the individual position deviation at the each irradiation position of the multiple charged particle beams.

6. The apparatus according to claim 5, wherein, in proportion to a ratio of an area deviated due to position deviation of a beam applied to a target pixel, the position deviation correction data generation circuit calculates a modulation rate of the beam applied to the target pixel, and a modulation rate of a beam applied to at least one of peripheral pixels surrounding the target pixel.

7. The apparatus according to claim 4, wherein
the defect correction data generation circuit calculates a plurality of distribution ratios for distributing the dose at the position associated with the defective beam to a plurality of positions on the periphery of the position associated with the defective beam, and
the plurality of distribution ratios are determined such that a gravity center position of the plurality of distribution ratios is located at the position associated with the defective beam.

8. A multiple charged particle beam writing method comprising:
forming multiple charged particle beams;
generating defect correction data which defines a dose modulation rate for performing correction by distributing a dose at a position associated with a defective beam, being always-OFF, in the multiple charged particle beams to at least one of other pixels, using a dose distribution in which each position in a unit region on a target object, corresponding to an irradiation region of a whole of the multiple charged particle beams, is defined by a uniform dose, regardless of writing pattern;
storing the defect correction data in a storage device;
calculating, for each writing pattern, an individual dose at each position on the target object, in accordance with a writing pattern concerned;
reading, for the each writing pattern, the defect correction data from the storage device, correcting the individual dose at the each position on the target object in accordance with the writing pattern concerned by performing a dose distribution using a value obtained by multiplying the individual dose at the each position on the target object by the dose modulation rate defined in the defect correction data having been read, and obtaining a corrected dose; and
writing the writing pattern on the target object by using the multiple charged particle beams with the corrected dose.

9. The method according to claim 8, wherein the defect correction data is generated by further using position deviation correction data for correcting an individual position deviation at each irradiation position of the multiple charged particle beams.

10. The method according to claim 8, wherein
the writing pattern is written on the target object by multiple writing, and
the defect correction data is generated so that correction of the dose at the position associated with the defective beam, performed in one of a plurality of passes of the multiple writing, is to be executed in at least one of other passes of the plurality of passes.
